(19) United States
(12) Patent Application Publication
(10) Pub. No.: US 2026/0371477 A1
(43) Pub. Date: Nov. 19, 2026

(54) VERTICAL BUSBARS FOR PRINTED CIRCUIT BOARDS

(71) Applicant: Würth Elektronik ICS GmbH & Co. KG, Niedernhall (DE)

(72) Inventors: Jakob Meyer, Krautheim-Neunstetten (DE); Michael Lindenberger, Künzelsau (DE)

(21) Appl. No.: 19/678,515

(22) Filed: May 15, 2026

(30) Foreign Application Priority Data
May 16, 2025 (DE) 10 2025 119 118.2

(51) Int. Cl. H05K 1/02

(52) U.S. Cl. CPC H05K 1/0263; H05K 2201/10272

(57) ABSTRACT

The present disclosure relates to a printed circuit board arrangement which has a printed circuit board on which at least one first electrical connection region is formed, and a busbar arrangement with a first busbar for transmitting an electrical current, wherein the first busbar has two opposite main surfaces which are connected at the periphery thereof by narrow sides. The first busbar has a first plug-in section and a spaced-apart second plug-in section which are formed on one or on corresponding narrow sides of the first busbar, wherein the first plug-in section forms at least one first plug-in pin and at least one corresponding plug-in bore for non-releasable fastening of the first plug-in pin is provided in the first electrical connection region. The second plug-in section forms at least one second plug-in pin, wherein a corresponding second plug-in bore of a second electrical connection region is provided for non-releasable fastening of the second plug-in pin.

### CROSS-REFERENCE TO RELATED APPLICATION

This application claims priority of the German patent application DE 10 2025 119 118.2 filed on May 16, 2025, which incorporated by reference herein in its entirety.

### TECHNICAL FIELD

The present disclosure relates to a printed circuit board arrangement which permits an efficient and reliable electrical connection. In particular, the present disclosure relates to a busbar arrangement having plug-in sections and plug-in pins which ensure non-releasable fastening to corresponding connection regions of the printed circuit board.

### BACKGROUND OF THE DISCLOSURE

In the field of printed circuit board arrangements, it is customary for electrical components and connections to be mounted on a printed circuit board in order to enable a multiplicity of electronic functions. Printed circuit boards serve as carriers for electronic components and enable the electrical connection between these components by means of conductor tracks. These connections are crucial for the functionality and performance of the electronic devices. Known systems typically comprise a multiplicity of conductor tracks which run on the surface or within the printed circuit board in order to transmit electrical signals and current.

Conductor tracks in printed circuit boards often come to thermal limits during the transmission of high currents and are often subject to losses. There is correspondingly a need for high currents to be transmitted safely and efficiently without endangering the integrity of the printed circuit board.

### SUMMARY OF THE DISCLOSURE

There may be a need to provide a flexible printed circuit board arrangement in which high currents can be transmitted in a robust and low-loss manner.

This need is met by means of a printed circuit board arrangement, a busbar arrangement and a method for producing a printed circuit board arrangement according to the independent claims.

According to a first aspect of the disclosure, a printed circuit board arrangement is described which has a printed circuit board on which at least one first electrical connection region is formed. The printed circuit board arrangement has a busbar arrangement with a first busbar for transmitting an electrical current, wherein the first busbar has two opposite main surfaces which are connected at the periphery thereof by narrow sides. The first busbar has a first plug-in section and a spaced-apart second plug-in section which are formed on one or on corresponding narrow sides of the first busbar. The first plug-in section forms at least one first plug-in pin. At least one corresponding plug-in bore for non-releasable fastening of the first plug-in pin is provided in the first electrical connection region. The second plug-in section forms at least one second plug-in pin, wherein a corresponding second plug-in bore of a second electrical connection region is provided for non-releasable fastening of the second plug-in pin.

According to a further aspect of the present disclosure, a busbar arrangement for a printed circuit board arrangement illustrated above is described.

According to a further aspect of the present disclosure, a method for producing the printed circuit board arrangement illustrated above is described.

The printed circuit board can have various shapes and sizes and is generally produced from materials such as FR4, a glass-fiber-reinforced epoxy resin. The printed circuit board (printed circuit board) is designed, for example, as a printed circuit board (PCB) and has a multiplicity of conductor tracks and coupling points for electronic components or electrical plugs. The printed circuit board has, at the corresponding electrical connection regions, in particular plug-in bores which are electrically coupled, for example, to an electronic component or to a conductor track of the printed circuit board. For example, the plug-in bores are coated on their inner sides with conductive material (for example by means of copper). Correspondingly, by means of plugging in a plug-in pin, the conductor track can provide an electrical connection between the conductor tracks and the plug-in pin via the coated plug-in bores.

A conductor track is a conductive element, typically composed of metal such as copper, which serves to transmit and distribute electrical energy efficiently. The first busbar has two opposite main surfaces which are connected at the periphery thereof by narrow sides. The first busbar has two opposite main surfaces which are connected at the periphery thereof by narrow sides. Main surfaces are the larger, opposite flat surfaces of the busbar, while narrow sides are the narrower, lateral edges which connect the main surfaces to one another. Busbars have, for example, a rectangular periphery, but can likewise have curved narrow sides. The conductor track extends in particular in a planar plane. In an exemplary embodiment, a conductor track can likewise have a curved profile. In other words, the main surfaces are curved and do not run in a planar plane. The conductor track distributes electrical current over a larger area, for example in comparison with a conductor track of the printed circuit board. The use of materials such as copper-tin or copper-zirconium alloys for conductor tracks which offer a high specific conductivity contributes to optimizing the electrical power.

The first busbar has a first plug-in section and a spaced-apart second plug-in section which are formed on one or on corresponding narrow sides of the first busbar. The first plug-in section forms at least one first plug-in pin, and at least the corresponding plug-in bore for non-releasable fastening of the first plug-in pin is provided in the first electrical connection region of the printed circuit board. A non-releasable connection is a connection which, after mounting, cannot be separated without destruction or damage to the components involved. Examples of non-releasable connections are soldered connections, adhesive connections or press-in connections. In particular, the plug-in pin forms a press-in pin which can be pressed into a plug-in bore in such a way that reversible release is impossible and, in particular, cannot be carried out without destruction.

In the track sections, a busbar can have, for example, one or a multiplicity of plug-in pins which can engage in the associated first or second electrical connection regions or the plug-in bores thereof of the printed circuit board. The plug-in pins can have, in a plug-in section of the busbar, for example an average distance of 0.5-5 mm, preferably 1-2.5 mm, particularly preferably 1.25-1.75 mm, in particular preferably 1.5 mm.

Since the plug-in pins are arranged on the narrow side and project from a narrow side along a planar plane in which at least one main surface runs, the busbars according to the disclosure form in particular vertical busbars. If the plug-in pins are fastened in the corresponding plug-in bores, a corresponding busbar is correspondingly fastened to a printed circuit board in such a way that the main faces are arranged orthogonal to a surface of the printed circuit board. In other words, a busbar plane (or the normal thereof) in which a main face of the busbar runs is orthogonal to a printed circuit board plane (or the normal thereof) in which the surface of the printed circuit board runs. In an exemplary embodiment, an angle of between 45° and 89° can be formed between a surface of the busbar and the surface of the printed circuit board. The busbar arrangement can be used in various applications, such as the board-to-wire connection, the measuring-Schunt function and the board-to-board connection. The different lengths of extent of the plug-in sections thus offer a versatile and efficient solution for the electrical connection and mechanical stability of printed circuit boards in various industrial applications.

By means of a vertical busbar, the main faces thereof are spaced apart from a surface of the printed circuit board. An additional installation space above the surface of the printed circuit board can thus be utilized. As a result, the busbar can have a larger area than, for example, the conductor tracks on or within the printed circuit board. This has the effect that the current density can be distributed better and thermal energy can additionally be emitted over larger areas of the busbar. Correspondingly, higher currents can thus be transmitted more efficiently. The busbars thus form an additional conductor path for a corresponding conductor track in the printed circuit board.

A further advantage is the modular design of the busbars, which enables a high degree of flexibility and standardization, as a result of which individual busbar geometries for various applications are dispensed with. This leads to cost savings and simpler mounting.

According to a further exemplary embodiment, the first connection region is electrically coupled to an electronic component of the printed circuit board. This means that the printed circuit board not only serves as a mechanical holder for the busbar, but also assumes an active role in the electrical circuit.

The electrical coupling between the connection region and the electronic component enables direct and efficient transmission of electrical signals and currents. This is particularly advantageous since it increases the overall efficiency of the printed circuit board arrangement and reduces the need for additional connections or components. The integration of an electronic component into the first connection region can extend the functionality of the printed circuit board and reduce the complexity of the circuit. The direct electrical coupling also improves the reliability of the connection since fewer contact resistances and potential fault sources are present. This can lead to improved performance and a longer lifetime of the entire printed circuit board arrangement. The combination of the mechanical fastening of the busbar with the electrical coupling of the connection region contributes to the modularity and flexibility of the printed circuit board arrangement since various electronic components can be easily integrated and replaced without extensive changes being required on the printed circuit board. This can lower the development and production costs and increase the adaptability of the printed circuit board arrangement to different applications and requirements.

According to a further exemplary embodiment, the first connection region has a coupling element, in particular a plug socket or a threaded socket, for coupling to external current and/or signal elements. A coupling element such as a plug socket enables a simple and secure connection between the printed circuit board arrangement and external components, as a result of which the flexibility and possible uses of the printed circuit board arrangement are considerably extended. A plug socket offers the advantage of a standardized interface which permits a rapid and reliable connection, which is of importance particularly in modular systems. By integrating a threaded socket, a mechanically stable and permanent connection can be provided which remains reliable even in the case of vibrations or mechanical loads. This is particularly advantageous in applications in which a high degree of modularity and flexibility are required, such as, for example, in power distribution units (PDUs), where targeted support of hotspots is necessary. The use of vertically pressable busbars in combination with such coupling elements can improve the heat dissipation and reduce the current density, which leads to a higher efficiency and reliability of the entire arrangement. Furthermore, the modular design of the busbars enables a simple adaptation to different requirements and geometries, as a result of which the need for individual solutions is dispensed with and the standardization is facilitated.

According to a further exemplary embodiment, the second electrical connection region is formed on the printed circuit board. A direct and efficient integration of the busbar arrangement into the printed circuit board is thereby possible. By forming the second electrical connection region directly on the printed circuit board, a stable and reliable connection between the busbar and the printed circuit board is ensured, which improves the mechanical integrity of the entire arrangement. This is particularly advantageous when it comes to supporting hotspots in power distribution units (PDUs) in a targeted manner since the busbars offer an increased area which contributes to the heat dissipation. The vertically pressable busbars enable an effective reduction of the current density in the printed circuit board, which in turn increases the lifetime and performance of the printed circuit board. The modular design of the busbars allows a wide variety of conductor tracks to be combined in a flexible manner.

According to a further exemplary embodiment, the second electrical connection region is formed spaced apart from the first electrical connection region. This configuration enables improved mechanical stability and electrical connection between the printed circuit board and the busbar. By the spaced-apart arrangement of the electrical connection regions, a uniform distribution of the mechanical load and the electrical currents is achieved. The vertically pressable busbars offer targeted support of hotspots in PDUs and, by virtue of their segmented construction, enable a high degree of modularity and standardization.

According to a further exemplary embodiment, an electrical connection region which electrically connects the first electrical connection region and the second electrical connection region to one another is formed on the printed circuit board between the first electrical connection region and the second electrical connection region. According to a further exemplary embodiment, the electrical connection region forms a conductor track on the surface and/or in the printed circuit board, which conductor track electrically couples the first electrical connection region to the second electrical connection region. This configuration permits an efficient and reliable electrical connection between different regions of the printed circuit board, as a result of which the busbar arrangement offers improved electrical performance and stability. The busbar or a plurality of busbars can be fastened to the printed circuit board, for example, in such a way that the busbars follow a profile of the conductor tracks and, so to speak, run congruently along the conductor tracks along the surface of the printed circuit board.

According to a further exemplary embodiment, the first busbar has connection pins between the first plug-in section and the second plug-in section on a narrow side, wherein the electrical connection region has plug-in bores. The connection pins are designed for non-releasable connection to the corresponding plug-in bores in the connection region.

A reliable and permanent connection between the busbar and the printed circuit board is thus made possible, as a result of which the stability and the electrical conductivity of the entire arrangement can be improved. By the additional mechanical connection by means of the connection pins, the mechanical stability of the printed circuit board arrangement is increased between the busbar and the printed circuit board, as a result of which vibrations and mechanical loads can be better resisted. Furthermore, the electrical connection is improved by the additional connection pins, which leads to a lower electrical resistance and more efficient current transmission. This is particularly advantageous in applications in which high currents have to be transmitted since the busbar offers a higher conductivity and the heat dissipation is improved.

According to a further exemplary embodiment, the connection pins and/or the plug-in pins, on the one hand, and the plug-in bores, on the other hand, are designed in such a way that the connection pins and/or the plug-in pins can be pressed into the plug-in bores for non-releasable connection. By means of a press-in mechanism, the plug-in pins and/or the connection pins are fastened to the printed circuit board by being pressed into the plug-in bores with a fixed and permanent connection. The pressability of the pins ensures a stable and reliable mechanical and electrical connection between the busbar and the printed circuit board. As a result of the pressing-in, a high contact force is generated which ensures a secure electrical connection and resists mechanical movements or vibrations. This is particularly advantageous in applications in which the printed circuit board arrangement is exposed to high mechanical loads or thermal cycles. The non-releasable connection prevents the unintentional release of the pins and thus increases the reliability of the entire printed circuit board arrangement. A further advantage of this embodiment is the simplification of the assembly process since no additional fastening elements such as screws or adhesives are required. The press-in connection also enables a more compact design of the printed circuit board arrangement since the pins can be pressed directly into the bores without requiring additional space for fastening elements. In particular, a high packing density of a multiplicity of vertical busbars on the printed circuit board can thus be made possible.

According to a further exemplary embodiment, the second electrical connection region and the first electrical connection region are electrically connected by means of the first busbar, and the first busbar bridges an intermediate region between the first electrical connection region and the second electrical connection region. According to a further exemplary embodiment, the intermediate region has a larger cross-sectional area, in particular a cross-sectional area which is more than 4 times larger, in particular more than 10 times larger, than an electrically conductive cross-sectional area of the connection region of the printed circuit board. The larger cross-sectional area of the intermediate region offers the advantage of increased mechanical stability and better distribution of the electrical load, as a result of which hotspots on the printed circuit board can be supported in a targeted manner. By increasing the area of the intermediate region, the heat dissipation is improved, which leads to a lower operating temperature of the printed circuit board and extends the lifetime of the electronic components. In addition, the efficiency of the current transmission is increased by the reduction of the resistance, which leads to a lower power loss and higher energy efficiency. By the targeted support of hotspots, cost savings of up to 40% can be achieved in the printed circuit boards since it is no longer necessary to increase the entire copper content by additional layers of the printed circuit board.

According to a further exemplary embodiment, the intermediate region has cooling structures, in particular cooling ribs, on the surface in order to increase the passive cooling effect. These cooling structures are arranged in the intermediate region of the busbar and serve for the effective heat dissipation, which is made possible by the enlargement of the surface of the busbar. The cooling ribs contribute to lowering the temperature of the busbar by dissipating the heat to the surroundings more efficiently. This is particularly advantageous in applications in which hotspots on the printed circuit board have to be supported in a targeted manner, such as in power distribution units (PDUs). The cooling structures not only improve the heat dissipation but also contribute to reducing the current density in the printed circuit board, which enables a better utilization of the plug-in pins and reduces the maximum current density.

According to a further exemplary embodiment, the intermediate region has a cooling duct which is designed to receive a cooling medium. This cooling duct serves for the efficient heat dissipation and improves the thermal performance of the printed circuit board arrangement. The cooling duct enables the circulation of a cooling medium, such as, for example, water or another suitable coolant, through the intermediate region of the busbar. As a result, the heat which is generated by the electrical current flow is effectively dissipated and the operating temperature of the printed circuit board is lowered. The cooling ducts can be integrated directly into the existing production lines without requiring additional work steps, which simplifies and accelerates the production processes.

According to a further exemplary embodiment, a further conductor track which passes through the busbar is formed on the surface and/or in the printed circuit board in the intermediate region of the printed circuit board. The busbar thus bridges a further conductor track with its intermediate region, with the result that a current bridge or signal bridge can be provided with the busbar via a further conductor track of the printed circuit board. This further conductor track enables an additional electrical connection or signal transmission which extends the functionality of the printed circuit board arrangement. The modularity of the printed circuit board arrangement is increased by the integration of a further conductor track in the intermediate region, which enables a flexible adaptation to different requirements and applications. The further conductor track can be formed both on the surface of the printed circuit board and within the printed circuit board, as a result of which optimum use of the available space and efficient distribution of the electrical signals is achieved.

According to a further exemplary embodiment, the busbar arrangement has a second busbar for transmitting an electrical current, wherein the second busbar has a third plug-in section and a spaced-apart fourth plug-in section which are formed on one or on corresponding narrow sides of the second busbar. The third plug-in section forms at least one third plug-in pin, wherein at least one corresponding plug-in bore for non-releasable fastening of the third plug-in pin is provided in the first electrical connection region. The fourth plug-in section of the second busbar forms at least one fourth plug-in pin, wherein a corresponding fourth plug-in bore of the second electrical connection region is provided for non-releasable fastening of the fourth plug-in pin. The second busbar can be formed correspondingly to the first busbar. The use of a second busbar offers the advantage of increased modularity and flexibility in the design of the printed circuit board arrangement. By virtue of the segmented design of the busbars, a wide variety of conductor tracks can be combined in a flexible manner. Furthermore, the second busbar contributes to the reduction of the electrical resistance and to the improvement of the heat dissipation by virtue of the area for the heat output being increased. The non-releasable fastening of the plug-in pins of the second busbar in the corresponding plug-in bores ensures a permanent and secure connection which withstands mechanical loads and increases the reliability of the electrical contacts. The integration of the second busbar into the printed circuit board arrangement additionally enables simpler and more efficient mounting since no additional components or work steps are required.

According to a further exemplary embodiment, the second busbar is arranged parallel to the first busbar. In particular, the second busbar can run parallel to the first busbar, for example, and can likewise be embodied in particular as a vertical busbar. The parallel arrangement of the busbars offers the possibility of simply and efficiently reproducing complex conductor tracks of the printed circuit board, and thus of reducing the current density in the reproduced conductor tracks.

According to a further exemplary embodiment, at least the first busbar has a first partial rail and a second partial rail, wherein the first partial rail has the first plug-in section and the second partial rail has the second plug-in section. The first partial rail has a first connection section with first connection pins which are designed for non-releasable connection to corresponding plug-in bores in the connection region, wherein the second partial rail has a second connection section with second connection pins which are designed for non-releasable connection to corresponding plug-in bores in the connection region. The first busbar can additionally be formed from three or more partial rails.

The first busbar is thus structurally separated into a first partial rail and into a second partial rail. Correspondingly, the first partial rail and the second partial rail can be arranged one behind the other along a linear direction or at an angle to one another. According to an exemplary embodiment, the first partial rail and the second partial rail are arranged spaced apart from one another. At the facing edge of the first partial rail with respect to the second partial rail, there can be a distance (air gap) or alternatively there can be a touch contact, with the result that a current flow can be provided via the facing edges. In the event of the first partial rail being spaced apart from the second partial rail, an electrical connection between the partial rails via the printed circuit board can be made possible. For example, the first partial rail can have the first connection section with first connection pins which form an electrical contact in corresponding plug-in bores of the printed circuit board in the connection region. Correspondingly, the second partial rail can have the second coupling section with the first connection pins in order to form an electrically conductive connection to corresponding plug-in bores of the printed circuit board in the connection region. The corresponding first and second connection pins and correspondingly the first partial rail and the second partial rail are electrically conductively connected via the connection regions.

The subdivision of the busbar into two partial rails enables increased modularity and flexibility in the design and mounting of the printed circuit board arrangement. This facilitates the adaptation to different conductor tracks and complex profiles, without individual busbar geometries having to be developed for each customer. The spatial separation of the partial rails makes optimum use of the area of the printed circuit board, which leads to a reduction of the current density and reduces the thermal load of the printed circuit board. The segmented design of the busbars contributes to the modularity of the printed circuit board arrangement, which enables a flexible adaptation to different requirements and eliminates the need for individual busbar geometries for various customers. The spaced-apart arrangement of the partial rails additionally enables a simple integration into existing production lines since no additional work steps are required.

According to an exemplary embodiment, the first partial rail extends from the first plug-in portion with a first extent length along a first extent direction to the first connecting section, and the second partial rail extends from the second plug-in portion with a second extent length along a second extent direction to the second connecting section. According to an exemplary embodiment, the first extent length is equal to the second extent length. Alternatively, in a further exemplary embodiment, the first extent length differs from the second extent length.

The first extent length and the second extent length relate to the length of the busbar along its main axis. The extent lengths relate in particular to the dimensions of the plug-in sections along the narrow sides of the busbar. By virtue of the different lengths of the extent sections, the busbar can be used in a flexible manner in different regions of the printed circuit board in order to ensure an optimum electrical connection and current transmission. This flexibility is particularly advantageous in applications in which different electrical components or regions of the printed circuit board have different requirements for the power supply. The use of busbars with variable lengths makes it possible to design the printed circuit board arrangement more efficiently. By virtue of the targeted placement of the busbar with different lengths, hotspots on the printed circuit board can be effectively supported and the maximum temperature can be reduced.

According to an exemplary embodiment, the first extent direction and the second extent direction are parallel to one another. In an alternative further exemplary embodiment, the first extent direction and the second extent direction are at an angle to one another, wherein the angle is, for example, between 45° and 125°, in particular 90°.

According to a further exemplary embodiment, at least the second busbar has a third partial rail and a fourth partial rail, wherein the third partial rail has the third plug-in section and the fourth partial rail has the fourth plug-in section, wherein the third partial rail has a third connection section with third connection pins which are designed for non-releasable connection to corresponding plug-in bores in the connection region. The fourth partial rail has a fourth connection section with fourth connection pins which are designed for non-releasable connection to corresponding plug-in bores in the second connection region. The second busbar can additionally be formed from three or more partial rails.

The partial rails are designed such that they each have specific plug-in sections and connection sections which enable a non-releasable connection to the printed circuit board. The third partial rail is equipped with a third plug-in section which contains third connection pins which are inserted into corresponding plug-in bores in the connection region of the printed circuit board. Analogously thereto, the fourth partial rail is provided with a fourth plug-in section which contains fourth connection pins which are inserted into corresponding plug-in bores in the second connection region of the printed circuit board. The subdivision of the busbars into partial rails enables increased modularity and flexibility in the design of the printed circuit board arrangement.

According to a further exemplary embodiment, the third partial rail extends from the third plug-in portion with a third extent length along a third extent direction to the third connection section, and the fourth partial rail extends from the fourth plug-in portion with a fourth extent length along a fourth extent direction to the fourth connection section.

According to a further exemplary embodiment, at least one of the first and second extent lengths differs from at least one of the third and fourth extent lengths.

The extent lengths relate to the dimensions of the partial rails along the narrow sides of the busbar. The variation in the extent lengths enables a flexible adaptation of the busbars to the specific requirements of the printed circuit board and the electrical connection regions thereof. By virtue of the different extent lengths, the busbars can be designed in such a way that they are matched in an optimum manner to the spatial circumstances and the electrical requirements of the printed circuit board. In particular, if the first busbar and the second busbar form a parallel profile in sections, it can be implemented by virtue of the configuration of the different extent lengths of the partial rails that the parting joints between the first and second partial rails of the first busbar and the fourth and fifth partial rails of the second busbar are at different points or not at the same point along the overall length of the first partial rail and the second partial rail. Temperature peaks at the transition regions of the partial rail in the printed circuit board can thus be reduced since the current flow of two partial rails through the printed circuit board is located at different positions of the printed circuit board.

According to an exemplary embodiment, the printed circuit board arrangement further has a connection element which is designed to form an electrical connection of an external electrical device to at least the first busbar. The connection element enables a direct and reliable connection directly to the corresponding busbar, as a result of which the functionality of the printed circuit board arrangement is extended. For the coupling of an external electrical device to the conductive structure of the printed circuit board, it is thus not necessary to generate a coupling on the printed circuit board itself via a coupling element, for example a plug socket, but rather the connection element can implement an electrical coupling along the busbar and transmit the transmitted electrical signals via the busbar to a corresponding component in the printed circuit board. The connection element can be realized, for example, by different plug connectors, clamps or other connecting elements. An advantage of this embodiment is the increased modularity and adaptability of the printed circuit board arrangement since it is now able to integrate external components without additional complex cabling or assembly processes. A further advantage is the improved heat dissipation by virtue of the increased area of the busbar which is not impaired by the connection element. The combination of vertically pressable busbars and the connection element enables targeted support of hotspots in PDUs and a high degree of modularity which promotes standardization and cost efficiency. The printed circuit board arrangement can thus be used in a wide field of use, from the connection of power elements to complex board-to-board connections, which considerably extends the versatility and possible uses.

According to a further exemplary embodiment, the connection element has a clamping device, by means of which the connection element can be clamped to at least the first busbar. The clamping device represents a mechanical connection which ensures reliable electrical contacting without additional tools or complex fastening methods being required. The use of a clamping device increases the flexibility and modularity of the printed circuit board arrangement since the connection element can be easily removed and fitted again if required. The clamping device can have, for example, two opposite clamping elements (clamping jaws), wherein the busbar can be clamped between the clamping elements. The clamping elements can be connected elastically to one another, for example, or can be adjusted and fixed with respect to one another, with the result that a gap between the clamping elements is adjustable. The clamping elements can themselves form planar regions in order to produce planar contact with the busbar. An efficient conductive contact connection can thus be produced.

According to a further exemplary embodiment, the connection element forms a measuring shunt (measuring shunt). A measuring shunt is a special component which is used for measuring electrical currents by virtue of a small, known resistance being inserted into the circuit. The voltage drop across this resistance is measured in order to calculate the current flowing through. The simple integration of a measuring shunt into the printed circuit board arrangement via the coupling to the busbar offers a plurality of advantages. On the one hand, this coupling enables precise current measurement directly on the printed circuit board, which reduces the need for external measuring devices and reduces the complexity of the circuit arrangement. Furthermore, the measuring shunt contributes to the improvement of the modularity of the printed circuit board arrangement since it can be used as a standardized element in various configurations. This supports the flexible adaptation of the printed circuit board arrangement to different requirements and applications without extensive changes being required on the basic structure. Furthermore, the use of a measuring shunt can contribute to optimizing the heat dissipation by virtue of it acting as an additional heat sink which dissipates the heat from the busbars. The vertically pressable busbars thus support the efficient connection and integration of the measuring shunt by virtue of ensuring a robust mechanical and electrical connection between the various components of the printed circuit board arrangement.

According to a further exemplary embodiment, the connection element is coupled to a wire-bound current conductor, with the result that an electrical connection between the current conductor and the first busbar can be provided by means of the connection element. The connection element permits an effective and reliable connection between the external current conductor and the busbar, as a result of which the electrical current can be transmitted efficiently. The coupling of the connection element to the wire-bound current conductor facilitates the integration of external current sources or external electronic components, which is of advantage particularly in complex electrical systems.

According to a further exemplary embodiment, the printed circuit board arrangement has a further printed circuit board, wherein the second electrical connection region is formed on the further printed circuit board. This configuration enables increased flexibility and modularity in the design of printed circuit board arrangements. The use of an additional printed circuit board provides the possibility of realizing complex electrical circuits which comprise a multiplicity of electrical components and connections. The further printed circuit board can act as a type of expansion module which provides additional functions or capacitances without excessively loading the main printed circuit board. This is particularly advantageous in applications in which a high density of electrical connections is required or in which different electrical circuits have to be integrated in a compact format. The connection between the main printed circuit board and the further printed circuit board takes place via the second electrical connection region which is formed on the additional printed circuit board. This type of connection enables efficient signal exchange and the transmission of high currents between the printed circuit boards, which increases the performance of the entire system. The modular design of the busbars allows a wide variety of conductor tracks of two separate printed circuit boards to be combined in a flexible manner with the busbars.

According to a further exemplary embodiment, the first plug-in section and the second plug-in section are arranged on the same narrow side of the first busbar, wherein the printed circuit board and the further printed circuit board are arranged next to one another (along a common planar plane) and the first busbar is coupled to the first electrical connection region of the printed circuit board and to the second electrical connection region. This permits an efficient and space-saving connection between the printed circuit boards since the busbar is pressed in vertically and thus ensures a stable and reliable electrical connection. By virtue of the vertical pressing-in of the busbar, hotspots in power distribution units (PDUs) are supported in a targeted manner, which leads to improved heat dissipation and a reduction of the electrical resistance. The vertically pressable busbar thus permits an efficient board-to-board connection which can transmit high currents and acts as a signal bridge, as a result of which efficient signal exchange between the printed circuit boards is made possible. The simple mounting of the busbar and the wide possible uses in various applications, such as, for example, in modular high-voltage boxes, contribute to the efficiency of the printed circuit board arrangement according to the disclosure. The different geometries of the busbar, such as straight, angled or with different contours, offer additional flexibility in the design of the printed circuit board arrangement and in particular the arrangement of different printed circuit boards which are connected to the busbars.

According to an exemplary embodiment, the first busbar has a first narrow side and a second narrow side adjoining the first narrow side, wherein the first narrow side and the second narrow side are at an angle to one another, wherein the angle is in particular 90°. The first plug-in section is formed on the first narrow side and the second plug-in section is formed on the second narrow side, with the result that the printed circuit board and the further printed circuit board can be arranged at an angle to one another. The printed circuit boards can thus be arranged at different angles to one another, with the result that a flexible and space-saving arrangement of the printed circuit boards is possible. The arrangement of the printed circuit boards at an angle to one another permits efficient use of the available space and at the same time provides the possibility of realizing complex electrical connections. The vertical pressability of the busbars supports the modularity and standardization of the printed circuit board arrangement, as a result of which a cost-effective and economical solution for the connection of printed circuit boards is provided.

According to a further exemplary embodiment, the first busbar has a first narrow side and a second narrow side lying opposite in relation to the main faces. The first narrow side and the second narrow side are formed parallel to and spaced apart from one another. The first plug-in section is formed on the first narrow side and the second plug-in section is formed on the second narrow side, with the result that the printed circuit board and the further printed circuit board can be arranged parallel to and spaced apart from one another. The parallel arrangement achieves optimized heat dissipation since the increased area of the busbars enables improved cooling by forced convection. Furthermore, the modular design of the busbars achieves a high degree of flexibility in the design of the conductor tracks.

It is pointed out that the embodiments described here represent only a limited selection of possible embodiment variants of the disclosure. It is thus possible to combine the features of individual embodiments with one another in a suitable manner, with the result that, for the person skilled in the art with the embodiment variants explicit here, a multiplicity of different embodiments are to be regarded as disclosed in an obvious manner. In particular, some embodiments of the disclosure are described using apparatus claims and other embodiments of the disclosure are described using method claims. However, the person skilled in the art will immediately become clear when reading this application that, unless explicitly stated otherwise, in addition to a combination of features which belong to one type of inventive subject matter, an arbitrary combination of features which belong to different types of inventive subject matter is also possible.

### BRIEF DESCRIPTION OF THE DRAWINGS

Exemplary embodiments are described in more detail below with reference to the appended drawings for further explanation and for better understanding of the present disclosure. In the drawings:

FIG. 1 shows a schematic illustration of an embodiment of a printed circuit board arrangement having a busbar and two electrical connection regions according to an exemplary embodiment of the present disclosure.

FIG. 2 shows an embodiment of a coupling element on a printed circuit board according to an exemplary embodiment of the present disclosure.

FIG. 3 shows a schematic illustration of a printed circuit board arrangement having a busbar and a plurality of electrical connection regions according to an exemplary embodiment of the present disclosure.

FIG. 4 shows a schematic illustration of a printed circuit board arrangement having a busbar which has two plug-in sections and corresponding plug-in pins for fastening in electrical connection regions according to an exemplary embodiment of the present disclosure.

FIG. 5 shows a schematic illustration of a printed circuit board arrangement having a plurality of busbars and electrical connection regions according to an exemplary embodiment of the present disclosure.

FIG. 6 shows a schematic illustration of a printed circuit board arrangement having a plurality of busbars and electrical connection regions according to an exemplary embodiment of the present disclosure.

FIG. 7 shows a schematic illustration of a printed circuit board arrangement having busbars which can be pressed in vertically according to an exemplary embodiment of the present disclosure.

FIG. 8 shows a schematic illustration of a printed circuit board arrangement having busbars which can be pressed in vertically according to an exemplary embodiment of the present disclosure.

FIG. 9 shows a schematic illustration of a printed circuit board arrangement having busbars which can be pressed in vertically according to an exemplary embodiment of the present disclosure.

FIG. 10 shows a schematic illustration of a connection element which is clamped to a busbar according to an exemplary embodiment of the present disclosure.

FIG. 11 shows a schematic illustration of a printed circuit board arrangement having busbars which can be pressed in vertically according to an exemplary embodiment of the present disclosure.

FIG. 12 shows a schematic illustration of a printed circuit board arrangement having a vertically arranged busbar between two printed circuit boards according to an exemplary embodiment of the present disclosure.

### DETAILED DESCRIPTION OF EXEMPLARY EMBODIMENTS

Identical or similar components in different figures are provided with identical reference numerals. The illustrations in the figures are schematic.

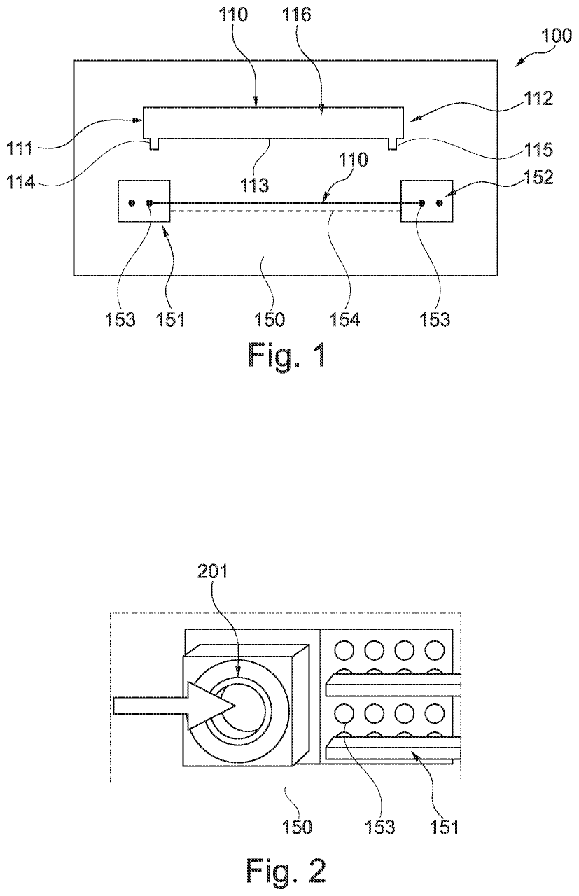

FIG. 1 shows a printed circuit board arrangement 100 having a busbar 110 and two electrical connection regions 151, 152 according to an exemplary embodiment of the present disclosure. FIG. 1 illustrates a plan view of the busbar 110 and the printed circuit board 150. For better illustration of the busbar 110, a folded-over side illustration of the busbars 110 is furthermore shown, in which side illustration the plug-in pins 114, 115 are illustrated.

The printed circuit board arrangement 100 has a printed circuit board 150 on which at least one first electrical connection region 151 is formed, and a busbar arrangement with a first busbar 110 for transmitting an electrical current. The first busbar 110 has two opposite main surfaces which are connected at the periphery thereof by narrow sides 113. The first busbar 110 has a first plug-in section 111 and a spaced-apart second plug-in section 112 which are formed on one or on corresponding narrow sides 113 of the first busbar 110, wherein the first plug-in section 111 forms at least one first plug-in pin 114 and at least one corresponding plug-in bore 153 for non-releasable fastening of the first plug-in pin 114 is provided in the first electrical connection region 151. The second plug-in section 112 forms at least one second plug-in pin 115, wherein a corresponding second plug-in bore 153 of a second electrical connection region is provided for non-releasable fastening of the second plug-in pin 115.

The printed circuit board 150 itself is produced from a material which offers both electrical insulation and mechanical stability. It serves as carrier for the electrical components and enables the integration of various electrical circuits and connections.

An electrical connection region 353 which electrically connects the first electrical connection region 151 and the second electrical connection region 152 is formed on the printed circuit board 150 between the first electrical connection region 151 and the second electrical connection region 152. The electrical connection region 353 comprises a conductor track 154 which is formed on the surface and/or in the printed circuit board 150.

The first busbar 110 bridges with an intermediate region 116 between the first electrical connection region 151 and the second electrical connection region 152. The intermediate region 116 has a larger cross-sectional area which is in particular more than 4 times larger, preferably more than 10 times larger, than the electrically conductive cross-sectional area of the conductor track 154 of the printed circuit board 150. This larger cross-sectional area serves for the reduction of the electrical resistance and for the improvement of the heat dissipation.

The plug-in pins 114, 115 and the plug-in bores 153 are designed in such a way that the plug-in pins can be pressed into the plug-in bores for non-releasable connection. This permits a stable and permanent electrical connection between the busbar 110 and the connection regions 151 and 152 of the printed circuit board 150.

FIG. 2 shows a detailed view of a printed circuit board arrangement which illustrates essential components and their interaction. The printed circuit board 150 has an electrical connection region 151.

The connection region 151 is provided with plug-in bores 153 which permit non-releasable fastening of plug-in pins. These plug-in bores 153 are dimensioned in order to ensure a secure and stable connection to the plug-in pins 114, 115. The plug-in bores 153 are designed such that they can receive the plug-in pins of the busbars 110 and fix them non-releasably by means of a press connection, as a result of which a reliable electrical connection is produced.

Next to the plug-in bores 153, a coupling element 201 can be seen which acts as a plug socket. This plug socket 201 is specifically designed for coupling external current and/or signal elements. It offers an interface for the connection to external devices and thus permits an extension of the functionality of the printed circuit board 150. The plug socket 201 is robust and can withstand mechanical loads which can occur during the connection to external components.

The components illustrated in FIG. 2 are part of a modular system which offers a high degree of flexibility and adaptability. The modular design of the busbars 110 allows different conductor tracks to be combined in a flexible manner, as a result of which the need for individual busbar geometries for each customer is dispensed with.

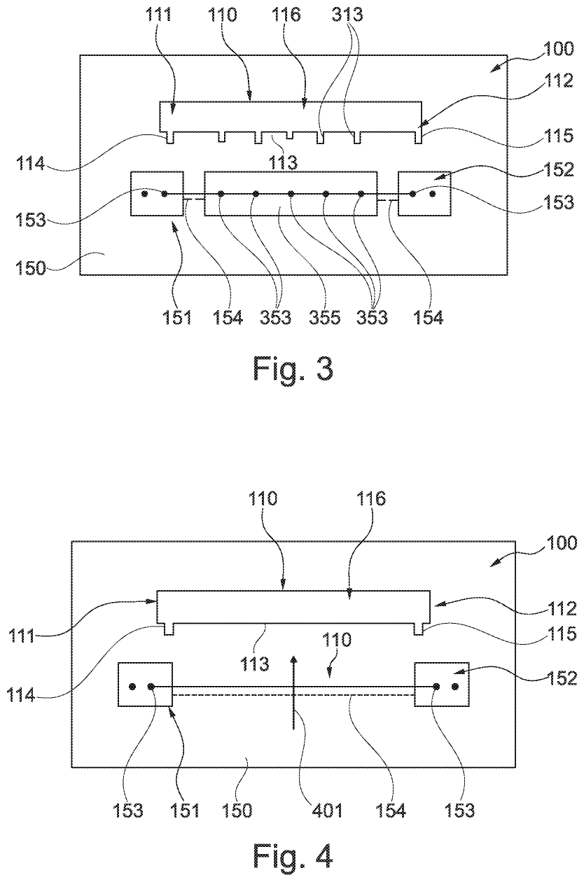

FIG. 3 shows a printed circuit board arrangement 100 having a printed circuit board 150 and a busbar 110. FIG. 3 illustrates a plan view of the busbar 110 and the printed circuit board 150. For better illustration of the busbar 110, a folded-over side illustration of the busbars 110 is furthermore shown, in which side illustration the plug-in pins 114, 115 are illustrated.

The busbar 110 has two opposite main surfaces which are connected by narrow sides 113. The busbar 110 comprises a first plug-in section 111 and a spaced-apart second plug-in section 112 which are each formed on the narrow sides 113.

The first plug-in section 111 forms at least one first plug-in pin 114 which is pressed into a corresponding plug-in bore 153 in a first electrical connection region 151 of the printed circuit board 150 for non-releasable fastening. The second plug-in section 112 forms at least one second plug-in pin 115 which is pressed into a corresponding plug-in bore 153 in a second electrical connection region 152 of the printed circuit board 150 for non-releasable fastening.

An electrical connection region 353 which electrically connects the two connection regions 151, 152 together with conductor tracks 154 is formed on the printed circuit board 150 between the first electrical connection region 151 and the second electrical connection region 152. The connection region 353 has plug-in bores 153 into which connection pins 313 of the busbar 110 can be pressed for non-releasable connection. The printed circuit board 150 is additionally provided with conductor tracks 154 which form the electrical connection region 353 and couple the electrical connection regions 151 and 152 to one another.

The busbar 110 bridges with an intermediate region 116 between the first electrical connection region 151 and the second electrical connection region 152. The intermediate region 116 has a larger cross-sectional area which is in particular more than 4 times larger, preferably more than 10 times larger, than the electrically conductive cross-sectional area of the conductor track 154 of the printed circuit board 150. This serves for the reduction of the electrical resistance and for the improvement of the heat dissipation.

The busbar 110 can have additional cooling structures, such as cooling ribs, on the surface in order to increase the passive cooling effect. Alternatively, the intermediate region 116 can contain a cooling duct for receiving a cooling medium.

The printed circuit board arrangement 100 enables a modular and cost-efficient solution for reinforcing the printed circuit board and for targeted support of hotspots. The vertically pressable busbars achieve a high degree of modularity which enables a standardization and flexible combination with different conductor tracks. This leads to a considerable improvement of the heat dissipation and a reduction of the current density in the printed circuit board, which contributes to cost savings and more efficient manufacturing.

FIG. 4 shows a printed circuit board arrangement 100 which comprises a printed circuit board 150 and a busbar arrangement having a first busbar 110. FIG. 4 illustrates a plan view of the busbar 110 and the printed circuit board 150. For better illustration of the busbar 110, a folded-over side illustration of the busbars 110 is furthermore shown, in which side illustration the plug-in pins 114, 115 are illustrated.

The printed circuit board 150 has at least one first electrical connection region 151 and one second electrical connection region 152. The first busbar 110 is provided for transmitting an electrical current and has two opposite main surfaces which are connected by narrow sides 113.

The first busbar 110 has a first plug-in section 111 and a spaced-apart second plug-in section 112 which are formed on the narrow sides 113 of the busbar. The first plug-in section 111 forms at least one first plug-in pin 114 which is provided for non-releasable fastening in a corresponding plug-in bore 153 of the first electrical connection region 151. The second plug-in section 112 forms at least one second plug-in pin 115 which is provided for non-releasable fastening in a corresponding plug-in bore 153 of the second electrical connection region 152.

A conductor track 154 which electrically connects the first electrical connection region 151 and the second electrical connection region 152 to one another is formed on the printed circuit board 150 between the first electrical connection region 151 and the second electrical connection region 152. The conductor track 154 is formed on the surface and/or in the printed circuit board 150. The first busbar 110 has, between the first plug-in section 111 and the second plug-in section 112, an intermediate region 116 which has a larger cross-sectional area than the electrically conductive cross-sectional area of the conductor track 154 of the printed circuit board 150. The intermediate region 116 can have cooling structures, in particular cooling ribs, on the surface in order to increase the passive cooling effect. In addition, the intermediate region 116 can have a cooling duct which is designed to receive a cooling medium.

In the intermediate region 116, the printed circuit board 150 can form a further conductor track 401 (for example as a signal path) on the surface and/or in the printed circuit board 150, which further conductor track passes through the busbar 110. The plug-in pins 114, 115 are designed in such a way that they can be pressed into the plug-in bores 153 for non-releasable connection.

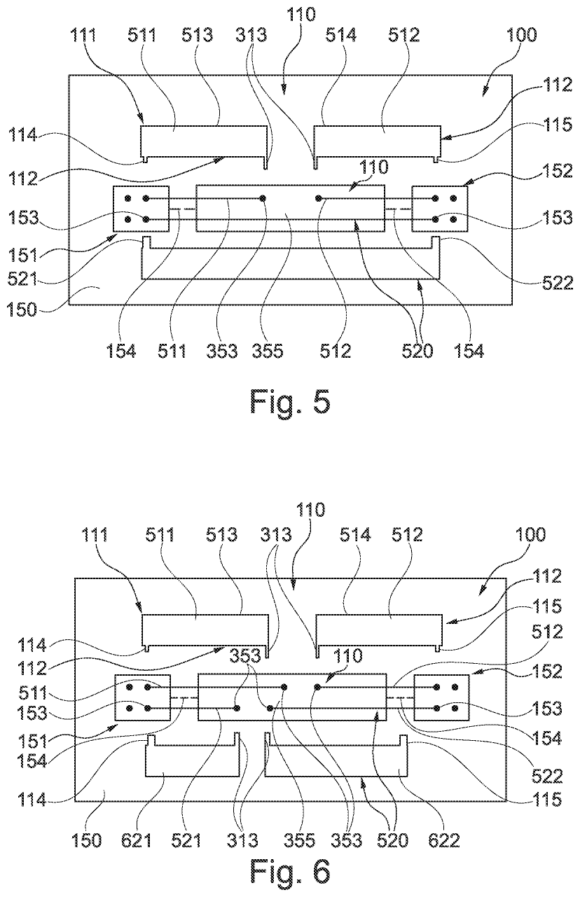

FIG. 5 shows a detailed illustration of a printed circuit board arrangement 100 which comprises a busbar arrangement. FIG. 5 illustrates a plan view of the busbar 110, the busbar 520 and the printed circuit board 150. For better illustration of the busbar 110 and the busbar 520, a folded-over side illustration of the busbars 110, 520 is furthermore shown, in which side illustration the plug-in pins 114, 115 and connection pins 313 are illustrated.

The printed circuit board 150 is equipped with a plurality of electrical connection regions, including the first connection region 151 and the second connection region 152. The busbar arrangement consists of a first busbar 110 and a second busbar 520 which both serve for transmitting electrical current.

The first busbar 110 is divided into two partial rails 511, 512. The first partial rail 511 has a first plug-in section 111 which is provided with a first plug-in pin 114. The plug-in pin 114 is formed for non-releasable fastening in a corresponding plug-in bore 153 of the first electrical connection region 151 of the printed circuit board 150. The second partial rail 512 is equipped with a second plug-in section 112 which has a second plug-in pin 115 which is provided for non-releasable fastening in a corresponding plug-in bore 153 of the second electrical connection region 152.

A connection region 355 of the printed circuit board 150 is characterized by a conductor track 154 and/or a connection terminal which electrically couple the first electrical connection region 151 to the second electrical connection region 152. The connection terminal has plug-in bores 353 which receive connection pins 313 of the first partial rail 151 and of the second partial rail 152, with the result that a current flow between the first partial rails 151 and second partial rails 152 is made possible via the connection terminal or connection terminal. The connection pins 313 can be pressed into the plug-in bores 153 of the electrical connection region 355 of the printed circuit board 150.

In particular, the flexibility of the busbar arrangement is illustrated. While the second busbar 520 connects the connection regions 151, 152 in one piece, the first busbar 110 can be provided divided into the first partial rail 511 and into the second partial rail 512. The arrangement of the busbars 110 and 520 enables efficient transmission of electrical currents between the different connection regions of the printed circuit board 150. The second busbar 520 runs parallel to the first busbar 110. The parallel arrangement of the busbars offers the possibility of simply and efficiently reproducing complex conductor tracks of the printed circuit board 150, and thus of reducing the current density in the reproduced conductor tracks. The modular design of the busbars 110, 520 increases the flexibility and adaptability of the printed circuit board arrangement by providing the possibility of combining different conductor tracks with the busbars.

FIG. 6 shows a detailed illustration of a printed circuit board arrangement 100 which illustrates a multiplicity of components and their connections. FIG. 6 illustrates a plan view of the busbar 110, the busbar 520 and the printed circuit board 150. For better illustration of the busbar 110 and the busbar 520, a folded-over side illustration of the busbars 110, 520 is furthermore shown, in which side illustration the plug-in pins 114, 115 and connection pins 313 are illustrated.

The first electrical connection region 151 and the second electrical connection region 152 are arranged on the printed circuit board 150 and are characterized by plug-in bores 153 which serve for receiving plug-in pins 114, 115.

The busbar arrangement comprises a first busbar 110 and a second busbar 520 which run parallel and are both designed for transmitting electrical current. The first busbar 110 has a first partial rail 511 and a second partial rail 512. These partial rails are equipped with plug-in sections 111 and 112 which each form plug-in pins 114 and 115. These plug-in pins 114, 115 are designed such that they can be pressed into the corresponding plug-in bores 153 of the electrical connection regions 151 and 152, as a result of which a non-releasable connection is produced.

The second busbar 520 is likewise segmented and consists of a third partial rail 621 and a fourth partial rail 622. These partial rails 621, 622 have plug-in sections 521 and 522 which are equipped with plug-in pins 114, 115 which can likewise be pressed into the plug-in bores 153 of the connection regions 151, 152. The parallel arrangement of the busbars 110 and 520 allows efficient current transmission and the possibility of flexibly combining different conductor tracks.

An electrical connection region 353 is formed on the printed circuit board 150 between the electrical connection regions 151 and 152. This region contains conductor tracks 154 which ensure the electrical connection between the connection regions and, for example, a connection terminal with plug-in bores 353. The connection pins 313 of the busbars are arranged on a first connection section 513 of the first partial rail 511 and on a second connection section 514 of the second partial rail 512 such that they can be pressed into the plug-in bores 353 of the connection region 355, as a result of which a stable and permanent connection is produced.

The partial rails 511, 512 of the first busbar 110 and the partial rails 621, 622 of the second busbar 520 run parallel to and are arranged spaced apart from one another. The extent length of the first partial rail 511 differs from the extent length of the third partial rail 621. In addition, the extent length of the second partial rail 512 differs from the extent length of the fourth partial rail 622. Correspondingly, it can be implemented by virtue of the configuration of the different extent lengths of the partial rails 511, 512, 621, 622 that the parting joints between the first and second partial rails 511, 512 of the first busbar 110 and the fourth and fifth partial rails 621, 622 of the second busbar 520 are at different points or not at the same point along the overall length of the first partial rail 110 and the second partial rail 520.

In addition, an intermediate region 355 is visible between the busbars 110 and 520, which intermediate region has a larger cross-sectional area in order to increase the cooling effect and to reduce the resistance of the conductor tracks. This construction supports the heat dissipation and contributes to reducing the current density in the printed circuit board, which leads to improved performance and efficiency of the printed circuit board arrangement.

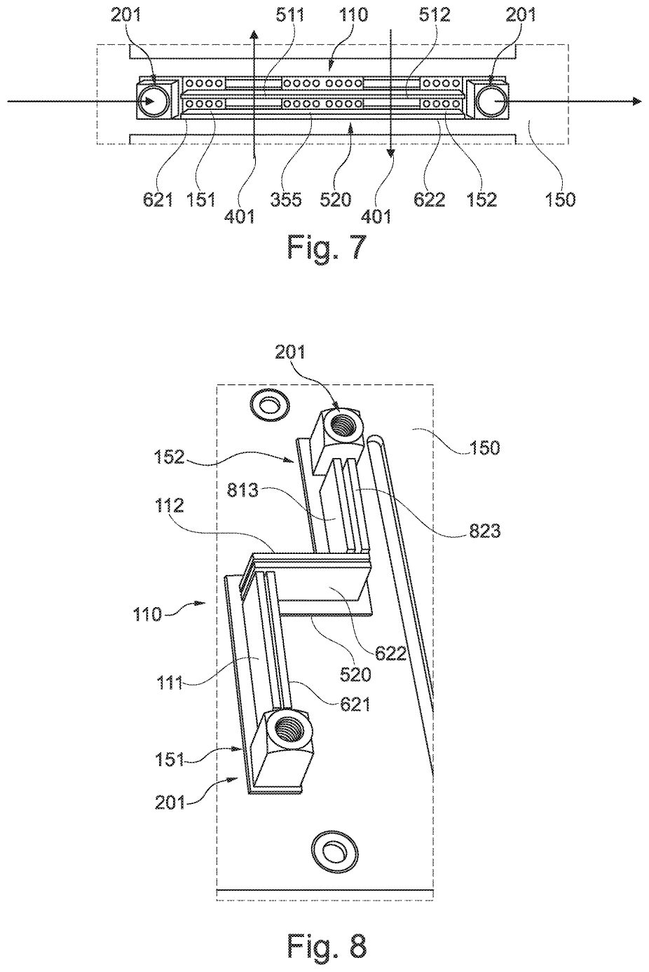

FIG. 7 shows a printed circuit board arrangement 100 which comprises a printed circuit board 150 on which a first electrical connection region 151 is formed and a second connection region 152 is arranged. A connection region 355 is illustrated between the first connection region 151 and the second connection region 152.

The printed circuit board arrangement 100 comprises a busbar arrangement with a first busbar 110 and a second busbar 520 for transmitting an electrical current. The embodiments in FIG. 7 correspond to the embodiment from FIG. 6, wherein the extent lengths of the partial rails 511, 522, 621, 622 are identical. The busbars 110 and 520 are arranged parallel to one another.

The first partial rail 511 and the second partial rail 512 are arranged spaced apart from one another and extend along a first extent direction and a second extent direction, respectively. The third partial rail 621 and the fourth partial rail 622 are likewise arranged spaced apart from one another and extend along a third extent direction and a fourth extent direction, respectively. An electrical connection region 355 which electrically connects the first electrical connection region 151 and the second electrical connection region 152 to one another is formed on the printed circuit board 150 between the first electrical connection region 151 and the second electrical connection region 152. The electrical connection region 355 comprises further conductor tracks (signal bridges) 401 on the surface and/or in the printed circuit board 150. The further conductor tracks 401 are bridged in particular by the respective partial rails 511, 522, 621, 622.

The connection pins 313 of the busbars 110, 520 are designed for non-releasable connection to corresponding plug-in bores 153 in the connection region 355. The plug-in pins 114, 115 of the first busbar 110 and the plug-in pins 114, 115 of the second busbar 520 can likewise be pressed into the plug-in bores 153 for non-releasable connection.

The printed circuit board 150 additionally has coupling elements 201, in particular plug sockets or threaded sockets, for coupling to external current and/or signal elements.

FIG. 8 shows a detailed view of a printed circuit board arrangement 100 which is equipped with busbars 110, 520 which can be pressed in vertically. The printed circuit board 150 is provided with a plurality of electrical connection regions. The busbar arrangement consists of a first busbar 110 and a second busbar 520 which each have three partial rails 511, 512, 813, 621, 622, 823 and plug-in pins.

The first busbar 110, 520 is designed such that it can be pressed with its plug-in pins 114, 115 vertically into the printed circuit board 150 in order to ensure a stable and non-releasable connection.

The second busbar 520 runs arranged parallel to the first busbar 110, which allows a compact and efficient structure.

A first plug socket 201 is provided on a first connection region 151 and a further plug socket 201 is provided on a second, opposite connection region 152.

In particular, the busbar 110 and the further busbar 520 each consist of 3 segments or partial rails 511, 512, 813, 621, 622, 823. The second partial rail 512 is arranged in particular orthogonal to the first partial rail 511 and the further partial rail 813 of the first busbar 110. Correspondingly, the fourth partial rail 622 is arranged orthogonal to the third partial rail 621 and the further partial rail 823. With the illustrated embodiment, a complex, non-linear profile can be provided along the printed circuit board 150, for example on account of the segmented busbars 110, 520. Furthermore, on account of the segmentation of the busbars 110, 520, a modular system can be provided with which a multiplicity of different non-linear profiles of the busbars 110, 520 can be achieved along a printed circuit board.

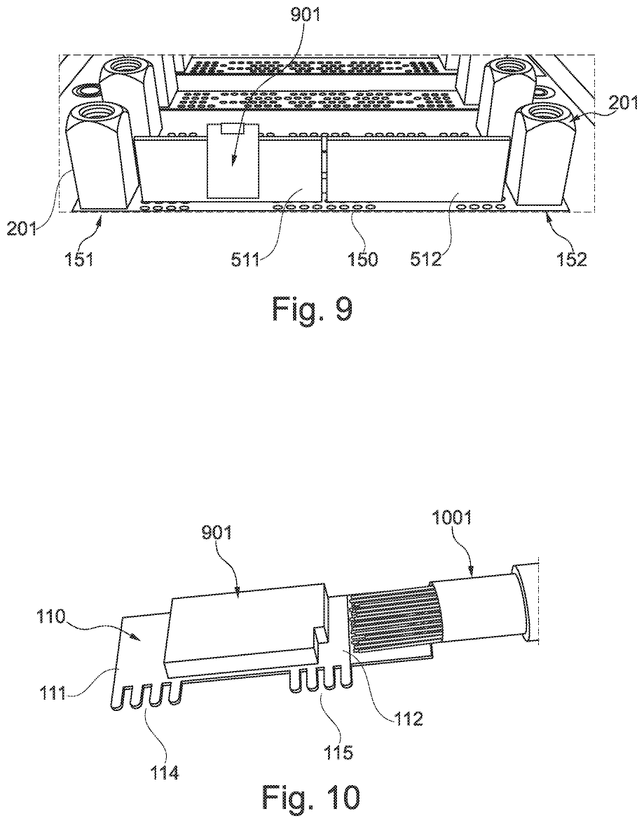

FIG. 9 shows a printed circuit board arrangement 100 which comprises a printed circuit board 150 on which at least one first electrical connection region 151 and one second electrical connection region 152 are formed. The printed circuit board 150 is provided with a busbar 110 which comprises a first partial rail 511 and a second partial rail 512. The first partial rail 511 is connected to the first electrical connection region 151, while the second busbar 512 is connected to the second electrical connection region 152. Both busbars can be pressed in vertically and offer non-releasable fastening by means of plug-in pins which are pressed into corresponding plug-in bores of the connection regions.

Furthermore, FIG. 9 shows a connection element 901 which serves for forming an electrical connection of an external electrical device to the first busbar 511. The connection element 901 is clamped to the busbar 110 and permits efficient current transmission.

The printed circuit board 150 is additionally equipped with a plurality of coupling elements 201 which serve as plug sockets and permit a connection to external current and/or signal elements. These coupling elements are positioned strategically on the electrical connection regions 151 and 152 in order to ensure optimum electrical coupling.

FIG. 10 shows a busbar arrangement which is designed for the electrical connection between a printed circuit board 150 and an external current conductor 1001. The busbar 110 is equipped with a first plug-in section 111 and a second plug-in section 112. These plug-in sections 111, 112 are designed such that they permit a non-releasable connection to corresponding plug-in bores 153 on a printed circuit board 150.

The first plug-in section 111 is formed on a narrow side 113 of the busbar 110 and has plug-in pins 114 which can be pressed into the corresponding plug-in bores 153 of the printed circuit board 150. The second plug-in section 112 is arranged spaced apart from the first plug-in section 111 and likewise has plug-in pins 115 which are provided for fastening in further plug-in bores 153.

A connection element 901 which produces an electrical connection to an external device is mounted on the busbar 110. This connection element can comprise a clamping device which permits the connection element 901 to be fastened securely to the busbar 110. The connection element 901 can also act as a measuring shunt in order to monitor the current intensity which flows through the busbar.

The external current conductor 1001 is connected to the connection element 901 and produces the connection between the busbar 110 and an external electrical source or load. The current conductor 1001 is typically a wire-bound conductor which ensures a secure and reliable current transmission.

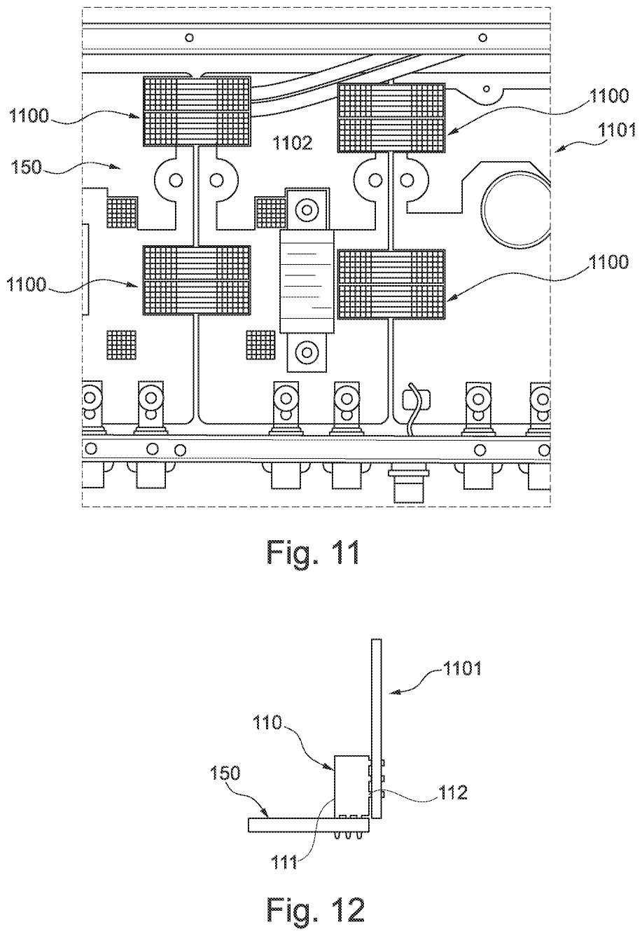

FIG. 11 shows a printed circuit board arrangement which comprises a plurality of busbar arrangements 1100 which can be pressed in and have busbars which can be pressed in vertically. The busbar arrangements 1100 are mounted on a main printed circuit board 150 and two further printed circuit boards 1101 and 1102. The main printed circuit board 150 and the further printed circuit boards 1101 and 1102 are arranged within a printed circuit board plane.

The printed circuit board arrangement in FIG. 11 shows that the busbar arrangements 1100 are mounted in different regions of the printed circuit boards 150, 1101, 1102 in order to ensure optimum distribution of the electrical current and efficient cooling.

The printed circuit board arrangement in FIG. 11 also shows the possibility of using the busbar arrangements 1100 as signal bridges in order to permit efficient signal exchange or current exchange between the printed circuit boards 150, 1101, 1102. In this case, the busbars of the busbar arrangements 1100 are designed in such a way that the first plug-in section 111 is pressed into plug-in bores of a printed circuit board 150, 1101, 1102 and the second plug-in section 112 is pressed into plug-in bores on an adjacent printed circuit board 150, 1101, 1102. In addition to the current exchange and signal exchange of the corresponding printed circuit boards 150, 1101, 1102, said printed circuit boards are additionally mechanically reinforced on account of the robust busbars of the busbar arrangements 1100.

FIG. 12 shows a printed circuit board arrangement 100 having a first printed circuit board 150 and a further printed circuit board 1101. The first busbar 110 is arranged between the two printed circuit boards 150 and 1101. The busbar 110 has a first plug-in section 111 and a spaced-apart second plug-in section 112. The first plug-in section 111 is pressed into the first printed circuit board 150, while the second plug-in section 112 is pressed into the further printed circuit board 1101.

The first plug-in section 111 and the second plug-in section 112 are formed on corresponding adjoining narrow sides of the busbar 110 and have plug-in pins 114, 115 which are pressed into corresponding plug-in bores 153 of the respective printed circuit boards 150, 1101.

The printed circuit board 150 and the further printed circuit board 1101 are arranged next to one another, wherein the first busbar 110 is coupled to the first electrical connection region 151 of the printed circuit board 150 and to the second electrical connection region 152 of the further printed circuit board 1101. The printed circuit board 150 and the further printed circuit board 1101 can be arranged at an angle to one another, wherein the angle is in particular 90°.

In addition, it should be pointed out that “comprising” does not exclude any other elements or steps and “a” or “an” does not exclude a multiplicity. Furthermore, it should be pointed out that features or steps which have been described with reference to one of the above exemplary embodiments can also be used in combination with other features or steps of other exemplary embodiments described above. Reference signs in the claims should not be regarded as a restriction.

List of reference signs:

```
  100 Printed circuit board arrangement
  110 First busbar
  111 First plug-in section
  112 Second plug-in section
  113 Narrow side
  114 First plug-in pin
  115 Second plug-in pin
  116 Intermediate region
  150 Printed circuit board
  151 First connection region
  152 Second connection region
  153 Plug-in bore
  154 Conductor track
  201 Plug socket
  313 Connection pin
  353 Plug-in bore
  355 Connection region
  401 Further conductor track
  511 First partial rail
  512 Second partial rail
  513 First connection section
  514 Second connection section
  520 Second busbar
  521 Third plug-in section
  522 Fourth plug-in section
  621 Third partial rail
  622 Fourth partial rail
  813 Further partial rail
  823 Further partial rail
  901 Connection element
1001 Current conductor
1100 Busbar arrangement
1101 Further printed circuit board
1102 Further printed circuit board
```

1. Printed circuit board arrangement, comprising
a printed circuit board on which at least one first electrical connection region is formed,
a busbar arrangement with a first busbar for transmitting an electrical current, wherein the first busbar has two opposite main surfaces which are connected at the periphery thereof by narrow sides,
wherein the first busbar has a first plug-in section and a spaced-apart second plug-in section which are formed on one or on corresponding narrow sides of the first busbar,
wherein the first plug-in section forms at least one first plug-in pin and
wherein at least one corresponding plug-in bore for non-releasable fastening of the first plug-in pin is provided in the first electrical connection region,
wherein the second plug-in section forms at least one second plug-in pin and
wherein a corresponding second plug-in bore of a second electrical connection region is provided for non-releasable fastening of the second plug-in pin.

2. Printed circuit board arrangement according to claim 1, comprising at least one of the following features:
wherein the busbar is fastened to a surface of the printed circuit board (15) in such a way that the main faces are orthogonal to the surface of the printed circuit board;
wherein the first connection region is electrically coupled to an electronic component of the printed circuit board;
wherein the first connection region has a coupling element, in particular a plug socket or a threaded socket, for coupling to external current and/or signal elements;
wherein the second electrical connection region is formed on the printed circuit board, and wherein the second electrical connection region is formed in particular spaced apart from the first electrical connection region;
wherein the connection pins and/or the plug-in pins, on the one hand, and the plug-in bores, on the other hand, are designed in such a way that the connection pins and/or the plug-in pins can be pressed into the plug-in bores for non-releasable connection.

3. Printed circuit board arrangement (100) according to claim 1,
wherein an electrical connection region which electrically connects the first electrical connection region and the second electrical connection region to one another is formed on the printed circuit board between the first electrical connection region and the second electrical connection region.

4. Printed circuit board arrangement according to claim 3,
wherein the electrical connection region forms a conductor track on the surface and/or in the printed circuit board, which conductor track electrically couples the first electrical connection region to the second electrical connection region, wherein the first busbar has preferably connection pins between the first plug-in section and the second plug-in section on a narrow side, wherein the electrical connection region has preferably plug-in bores, wherein the connection pins are designed for non-releasable connection to the corresponding plug-in bores in the connection region.

5. Printed circuit board arrangement according to claim 1,
wherein the second electrical connection region and the first electrical connection region are electrically connected by means of the first busbar, and the first busbar bridges an intermediate region between the first electrical connection region and the second electrical connection region.

6. Printed circuit board arrangement according to claim 5,
wherein the intermediate region has a larger cross-sectional area, in particular a cross-sectional area which is more than 4 times larger, in particular more than 10 times larger, than an electrically conductive cross-sectional area of the connection region of the printed circuit board

7. Printed circuit board arrangement (100) according to claim 6,
wherein the intermediate region (116) has cooling structures, in particular cooling ribs, on the surface in order to increase a passive cooling effect.

8. Printed circuit board arrangement (100) according to claim 6,
wherein the intermediate region (116) has a cooling duct which is designed to receive a cooling medium.

9. Printed circuit board arrangement according to claim 5,
wherein, in the intermediate region, the printed circuit board forms a further conductor track on the surface and/or in the printed circuit board, which further conductor track passes through the busbar.

10. Printed circuit board arrangement according to claim 1,
wherein the busbar arrangement has a second busbar for transmitting an electrical current,
wherein the second busbar has a third plug-in section and a spaced-apart fourth plug-in section which are formed on one or on corresponding narrow sides of the second busbar,
wherein the third plug-in section forms at least one third plug-in pin and wherein at least one corresponding plug-in bore for non-releasable fastening of the third plug-in pin is provided in the first electrical connection region,
wherein the fourth plug-in section of the second busbar forms at least one fourth plug-in pin and wherein a corresponding fourth plug-in bore of the second electrical connection region is provided for non-releasable fastening of the fourth plug-in pin, wherein the second busbar is preferably arranged parallel to the first busbar, wherein at least the first busbar has preferably a first partial rail and a second partial rail, wherein the first partial rail has the first plug-in section and the second partial rail has the second plug-in section,
wherein the first partial rail has preferably a first connection section with first connection pins which are designed for non-releasable connection to corresponding plug-in bores in the connection region, wherein the second partial rail has preferably a second connection section with second connection pins which are designed for non-releasable connection to corresponding plug-in bores in the connection region.

11. Printed circuit board arrangement according to claim 10,
wherein the first partial rail and the second partial rail are arranged spaced apart from one another.

12. Printed circuit board arrangement according to claim 10,
wherein the first partial rail extends from the first plug-in portion with a first extent length along a first extent direction to the first connecting portion, and the second partial rail extends from the second plug-in portion with a second extent length along a second extent direction to the second connecting portion wherein the first extent length and the second extent length preferably are of different lengths.

13. Printed circuit board arrangement (100) according to claim 12,
wherein the first extent direction and the second extent direction are parallel to one another, or
wherein the first extent direction and the second extent direction are at an angle to one another, wherein the angle is in particular 90°.

14. Printed circuit board arrangement according to claim 10,
wherein at least the second busbar has a third partial rail and a fourth partial rail, wherein the third partial rail has the third plug-in section and the fourth partial rail has the fourth plug-in section,
wherein the third partial rail has a third connection section with third connection pins which are designed for non-releasable connection to corresponding plug-in bores in the connection region,
wherein the fourth partial rail has a fourth connection section with fourth connection pins which are designed for non-releasable connection to corresponding plug-in bores in the second connection region wherein the third partial rail preferably extends from the third plug-in portion with a third extent length along a third extent direction to the third connection section, and the fourth partial rail preferably extends from the fourth plug-in portion with a fourth extent length along a fourth extent direction to the fourth connection section wherein at least one of the first and second extent lengths preferably differs from at least one of the third and fourth extent lengths.

15. Printed circuit board arrangement according to claim 1, further comprising
a connection element which is designed to form an electrical connection of an external electrical device to at least the first busbar.

16. Printed circuit board arrangement according to claim 15,
wherein the connection element preferably has a clamping device, by means of which the connection element can be clamped to at least the first busbar wherein the connection element preferably forms a measuring shunt, and
wherein the connection element is preferably coupled to a wire-bound current conductor, with the result that an electrical connection between the current conductor and the first busbar can be provided by means of the connection element.

17. Printed circuit board arrangement according to claim 1, further comprising
a further printed circuit board,
wherein the second electrical connection region is formed on the further printed circuit board.

18. Printed circuit board arrangement according to claim 17, further comprising at least one of the following features:
wherein the first plug-in section and the second plug-in section are arranged on the same narrow side of the first busbar,
wherein the printed circuit board and the further printed circuit board are arranged next to one another and the first busbar is coupled to the first electrical connection region of the printed circuit board and to the second electrical connection region; wherein the first busbar has a first narrow side and a second narrow side adjoining the first narrow side, wherein the first narrow side and the second narrow side are at an angle to one another, wherein the angle is in particular 90°, wherein the first plug-in section is formed on the first narrow side and the second plug-in section is formed on the second narrow side, with the result that the printed circuit board and the further printed circuit board can be arranged at an angle to one another;
wherein the first busbar has a first narrow side and a second narrow side lying opposite in relation to the main faces, wherein the first narrow side and the second narrow side are formed parallel to and spaced apart from one another, wherein the first plug-in section is formed on the first narrow side and the second plug-in section is formed on the second narrow side, with the result that the printed circuit board and the further printed circuit board can be arranged parallel to and spaced apart from one another.

19. Busbar arrangement for a printed circuit board arrangement according to one 1, the busbar arrangement comprising:
a first busbar for transmitting an electrical current, wherein the first busbar has two opposite main surfaces which are connected at the periphery thereof by narrow sides,
wherein the first busbar has a first plug-in section and a spaced-apart second plug-in section which are formed on one or on corresponding narrow sides of the first busbar,
wherein the first plug-in section forms at least one first plug-in pin which is formed for non-releasable fastening in a corresponding plug-in bore of a first electrical connection region of a printed circuit board,
wherein the second plug-in section forms at least one second plug-in pin which is formed for non-releasable fastening in a corresponding plug-in bore of a second electrical connection region.

20. Method for producing a printed circuit board arrangement according to claim 1.
